(19) United States
(12) Patent Application Publication
(10) Pub. No.: US 2011/0260299 A1
(43) Pub. Date: Oct. 27, 2011

(54) METHOD FOR VIA PLATING IN ELECTRONIC PACKAGES CONTAINING FLUOROPOLYMER DIELECTRIC LAYERS

(75) Inventors: Robert D. Edwards, Binghamton, NY (US); Frank D. Egitto, Binghamton, NY (US); Luis J. Matienzo, Endicott, NY (US); Susan Pitely, Vestal, NY (US); Daniel C. Van Hart, Conklin, NY (US)

(73) Assignee: ENDICOTT INTERCONNECT TECHNOLOGIES, INC., Endicott, NY (US)

(21) Appl. No.: 12/765,110

(22) Filed: Apr. 22, 2010

(51) Int. Cl. H01L 23/50; H05K 3/00; H01L 21/441

(52) U.S. Cl. 257/632; 438/687; 216/18; 257/E21.46; 257/E21.477; 257/E23.079

(57) ABSTRACT

A semiconductor printed circuit board assembly (PCBA) and method for making same for use in electronic packages having a core layer of copper-invar-copper (CIC) with a layer of dielectric substrate placed on the core layer. A second layer of dielectric substrate is placed on the lower surface of the core layer of CIC. The layers are laminated together. Blind vias are laser drilled into the layers of dielectric substrate. The partially completed PCBA is subjected to a reactive ion etch (RIE) plasma as a first step to clean blind vias in the PCBA. After the plasma etch, an acidic etchant liquid solution is used on the blind vias. Pre-plating cleaning of blind vias removes a majority of oxides from the blind vias. Seed copper layers are then applied to the PCBA, followed by a layer of copper plating that can be etched to meet the requirements of the PCBA.

### FIELD OF THE INVENTION

The present invention relates to manufacturing and preparation of circuit boards and, more specifically, to a method for successful plating of blind vias made in microelectronic circuits containing fluoropolymer (FP) dielectric layers.

### BACKGROUND OF THE INVENTION

The needs of the semiconductor marketplace continue to drive density into semiconductor packages. Traditionally, greater wiring densities have been achieved by reducing the dimensions of vias, lines, and spaces, increasing the number of wiring layers, and utilizing blind and buried vias. However, each of these approaches, for example, those related to drilling and plating of high aspect ratio vias, reduced conductance of narrow circuit lines, and increased cost of fabrication related to additional wiring layers, includes inherent limitations. One method of extending wiring density beyond the limits imposed by these approaches allows for metal-to-metal z-axis interconnection of sub-composites during lamination to form a composite structure.

Conductive joints can be formed during lamination using an electrically conductive adhesive. As a result, one is able to fabricate structures with vertically terminated vias of arbitrary depth. Replacement of conventional plated through holes with vertically-terminated vias opens up additional wiring channels on layers above and below the terminated vias and eliminates via stubs which cause reflective signal loss. More and more substrate designs require signal paths that can handle frequencies on the order of multi-gigahertz.

Laser ablation, referred to herein as laser drilling, of blind vias into FP-containing laminates leaves a thin layer of debris at the bottom of the via. The debris is composed of dielectric layer fillers, FP segments, and copper oxides distributed at the bottom of the blind via. Methods for removal of laser debris from drilling usually contain wet-line pre-cleans and de-smears as a preparation step to copper plating. These approaches do not remove the debris that is firmly attached to the bottom and sidewalls of the blind via. Even conventional plasma processes used to remove other organic layers do not have efficient etching yields for FP materials resident within the via.

Applicants use a reactive ion etch (RIE) plasma of tetrafluoromethane (CF₄) and oxygen (O₂), in addition to etching a portion of the FP smear itself, to attack any of the exposed copper or oxides present at the bottom of the blind via. Domains of copper oxyfluoride form, and are mixed with FP residues and filler. This metal oxyfluoride present at the bottom of the blind vias can decompose in humid environments >40% R.H. to yield HF and CuO. The addition of an acidic etchant such as HL-41 solution following the plasma treatment augments the removal of the oxide layer and the remaining FP segments from the bottom of the blind via. This newly exposed surface is amenable to plating. It contains a thin oxide layer of copper oxide on the order of <30 angstroms, as measured by Auger Electron Spectroscopy (AES) depth profiling, that are easily removed by conventional pre-plating cleaning methods to provide an ideal surface for the copper plating.

Methods for removal of laser debris from drilling usually contain wet-line pre-cleans and de-smears as a preparation step to copper plating. These approaches do not remove the debris that is firmly attached to the bottom and sidewalls of the blind via and the layer of FP smear is the result. The layer of FP smear might result in the copper plating delaminating from copper layer while under stress thereby causing a discontinuity within composite structure that causes a failure of the via.

It is therefore an object of the invention to utilize a combined approach to cleaning vias using a reactive ion etch (RIE) plasma of tetrafluoromethane (CF₄) and oxygen (O₂) in sequence with an acidic etchant such as an HL-41 solution to create a surface that is amenable for plating.

A further object of the invention is directed to oxidizing and fluorinating the exposed copper and oxides present at the bottom of a blind via to undercut FP residues and filler debris for subsequent removal.

Another object of the invention is directed to using the disclosed process with other laser drilled dielectric substrate polymers, such as FR4 (a glass reinforced epoxy), polyimide, polytetrafluoroethylene, polyimide (Kapton), polyester (Mylar), FEP (Teflon), fluoropolymer (FP), or other dielectric known to those skilled in the arts.

### DISCUSSION OF RELATED ART

U.S. Pat. No. 7,063,800, by Ding, et al., granted Jun. 20, 2006 for METHODS OF CLEANING COPPER SURFACES IN THE MANUFACTURE OF PRINTED CIRCUIT BOARDS discloses a method of microetching a metal substrate by contacting the substrate with an aqueous composition comprising a sodium persulfate or hydrogen peroxide oxidizing agent, acid, and one or more additives. When the oxidizing agent is sodium persulfate, the one or more additives generally comprise an aliphatic saturated dicarboxylic acid. When the oxidizing agent is hydrogen peroxide, the one or more additives generally comprise a stabilizer and amino tris(methylene phosphonic acid).

U.S. Pat. No. 6,373,717, by Downes, Jr., et al., granted Apr. 16, 2002 for ELECTRONIC PACKAGE WITH HIGH DENSITY INTERCONNECT LAYER discloses an electronic package, and method of making the electronic package. The package includes a semiconductor chip and a multi-layered interconnect structure having a high density interconnect layer such as an allylated surface layer. The semiconductor chip includes a plurality of contact members on one of its surfaces that are connected to the multi-layered interconnect structure by a plurality of solder connections. The multi-layered interconnect structure is adapted for electrically interconnecting the semiconductor chip to a circuitized substrate (e.g., circuit board) with another plurality of solder connections and includes a thermally conductive layer comprising a material having a selected thickness and coefficient of thermal expansion to substantially prevent failure of the solder connections between said first plurality of electrically conductive members and the semiconductor chip. The electronic package further includes a dielectric material having an effective modulus to assure sufficient compliancy of the multi-layered interconnect structure during operation. The allylated surface layer can withstand thermal stresses that arise during thermal cycling operation of the electronic package.

U.S. Pat. No. 5,910,255, by Noddin, granted Jun. 8, 1999 for METHOD OF SEQUENTIAL LASER PROCESSING TO EFFICIENTLY MANUFACTURE MODULES REQUIRING LARGE VOLUMETRIC DENSITY MATERIAL REMOVAL FOR microvia FORMATION discloses a method for forming a blind via in a laminated substrate by laser drilling a blind via from a top surface of the substrate toward a bottom surface of the substrate using a first laser and a first trepanning motion of a laser focal spot of the first laser. Then, the via is laser drilled from the top surface toward the bottom surface using a second laser and a second trepanning motion of a laser focal spot of the second laser.

U.S. Pat. No. 6,131,279, by Jones, et al., granted Oct. 17, 2000 for INTEGRATED MANUFACTURING PACKAGING PROCESS discloses a process of fabricating a circuitized substrate which comprises the steps of providing an organic substrate having circuitry thereon and applying a dielectric film on the organic substrate, forming microvias in the dielectric film and sputtering a metal seed layer on the dielectric film and in the microvias, then plating a metallic layer on the metal seed layer and forming a circuit pattern thereon.

United States Published Patent Application No. 2006/0091023, published May 4, 2006, by Bukhari et al., for METHOD FOR FABRICATING ELECTRICAL CONNECTING ELEMENTS, AND CONNECTING ELEMENT discloses methods and systems of assessing microvia formation in a substrate manufacturing process. In one embodiment of the invention, a microvia opening is drilled through a top dielectric layer of a multilayer printed circuit board (PCB) substrate, The multilayer PCB substrate includes the microvia opening. The opening is desmeared down to a capture pad in a conductive layer; and a sequential electrochemical reduction analysis is performed over the capture pad within the microvia opening to detect any existing contamination in the bottom of the microvia opening. If a contaminant is found, production is halted and appropriate actions are taken to understand the source of contamination.

United States Published Patent Application No. 2003/0121146, published Jul. 3, 2003, by Schmidt, for METHOD FOR FABRICATING ELECTRICAL CONNECTING ELEMENTS, AND CONNECTING ELEMENT, discloses a micro perforation process step that is combined with the lamination process. To this end, a dielectric layer and a prefabricated product are placed between a support and a perforation die. The prefabricated product is partially covered by a conducting layer forming structures to be contacted by microvias. Pressure is applied on the perforation die, perforation tips of the perforation die forming microvias for contacting the structures. A surface of the dielectric layer or the prefabricated product is configured or coated, so that the prefabricated product and the dielectric layer stick to each other after the pressure has been applied.

United States Published Patent Application No. 2006/0278254, published Dec. 14, 2006, by Jackson, for METHOD AND APPARATUS FOR TREATING A SUBSTRATE WITH DENSE FLUID AND PLASMA, discloses a method, process and apparatus for selective cleaning, drying, and modifying substrate surfaces and depositing thin films thereon using a dense phase gas solvent and admixtures within a first created supercritical fluid anti-solvent. Dense fluids are used in combination plasma adjuncts to enhance substrate surface cleaning, modification, precision drying and deposition processes therein. Moreover, conventional wet cleaning agents such as hydrofluoric acid and ammonium fluoride may be used to perform substrate pre-treatments prior to precision drying and cleaning treatments. Finally, dense fluid such as solid phase carbon dioxide and argon may be used as a follow-on treatment or in combination with plasmas to further treat a substrate surface.

United States Published Patent Application No. 2002/0170891, published Nov. 21, 2002, by Boyle, et al., for LASER MACHINING SYSTEM AND METHOD, discloses a substrate machined to form, for example, a via. The substrate is in a chamber within which the gaseous environment is controlled. The machining laser beam is delivered with control of parameters such as pulsing parameters to achieve desired effects. The gaseous environment may be controlled to control integral development of an insulating lining for a via. Also, machining may be performed in multiple passes in order to minimize thermal damage and to achieve other desired effects such as a particular via geometry.

The previously outlined United States issued patents and applications fail to adequately describe or disclose the present invention.

### SUMMARY OF THE INVENTION

According to the present invention, there is provided a method for making a semiconductor printed circuit board assembly (PCBA) for use in electronic packages having a core layer of copper-invar-copper (CIC) with a layer of dielectric substrate placed on the core layer and a second layer of dielectric substrate placed on the lower surface of the core layer, laminating the layers together, forming a first assembly step. Then, blind vias are laser drilled into the layers of dielectric substrate. After a reactive ion plasma etch, an acidic etchant liquid solution is used as a second cleaning method on the blind vias prior to a first pre-plating cleaning of blind vias which removes any oxides therefrom. Seed copper layers are then applied to the PCBA, followed by a layer of copper plating that can be etched to meet the requirements of the PCBA.

### BRIEF DESCRIPTION OF THE DRAWINGS

These and other features and advantages of this invention will be more readily understood from the following detailed description of the various aspects of the invention taken in conjunction with the accompanying drawings in which:

FIG. 1 is a flow chart of process steps in accordance with the invention;

FIG. 2 shows a scanning electron microscope image of an FP smear debris field after an FP layer is laser drilled prior to cleaning;

FIGS. 3a-d show a graphical representation of Auger Electron Spectroscopy (AES) scans of a blind via after plasma cleaning;

FIGS. 4a-d show a graphical representation of AES scans of a blind via after plasma cleaning combined with wet cleaning;

FIG. 5 shows a sectional view of two blind vias on opposing sides of a CIC layer, the top one being plasma etch cleaned only, the opposite blind via having been cleaned with plasma etching and then a subsequent acidic etchant process; and

FIGS. 6a-b shows scanning electron microscope images of the surfaces of blind vias following plasma treatment and HL-41 treatments.

It is noted that the drawings of the invention are not to scale. The drawings are merely schematic representations, not intended to portray specific parameters of the invention. The drawings are intended to depict only typical embodiments of the invention, and therefore should not be considered as limiting the scope of the invention. For the sake of clarity and brevity, like elements and components of each embodiment will bear the same designations throughout the description.

### DESCRIPTION OF THE PREFERRED EMBODIMENT

In the invention, a method is provided for plating blind vias in microelectronic circuits containing fluoropolymer (FP) dielectric layers.

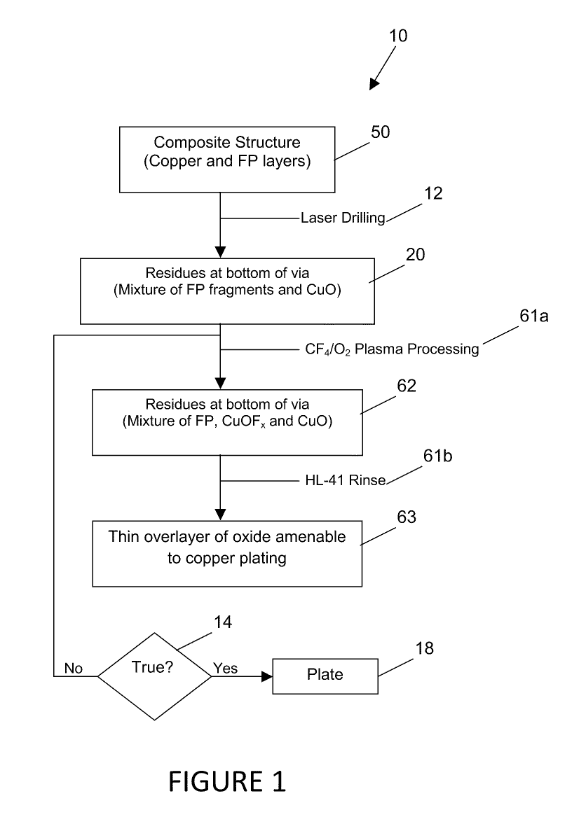

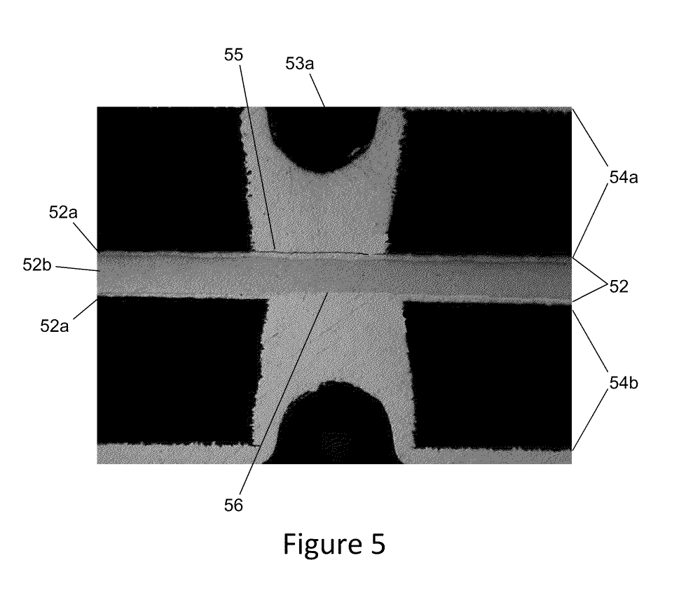

Referring now to FIGS. 1 and 5, a flowchart 10 of process steps is shown. Laser drilling 12 is used to form blind vias in a composite structure 50 of Copper-Invar-Copper (CIC) 52 (FIG. 5) and FP layers 54a, and 54b. The FP smear 20 left after laser drilling 12 is then treated with a reactive ion etch (RIE) plasma of tetrafluoromethane (CF₄) and oxygen (O₂) 61a as a cleaning treatment step. In addition to etching a portion of the FP smear 20 itself, the plasma attacks any of the exposed copper or oxides present at the bottom of the blind via 53a.

Domains of copper oxyfluoride form and are mixed with the FP residues and filler that remain. The metal oxyfluoride 62 present at the bottom of the blind vias can decompose in humid environments >40% R.H. to yield HF and CuO. The addition of an acidic etchant such as HL-41 solution rinse 61b following the plasma treatment 61a augments the removal of the oxide layer 62 and the remaining FP segments from the bottom of the blind via.

The process leaves a thin layer of oxide 63 that is amenable for copper plating 57. If the process is deemed not to have an amenable surface for plating 14, then the operation returns to the RIE stage 61a. If the process is deemed to have an amenable surface for plating 14, however, then the operation moves to the plating process 18.

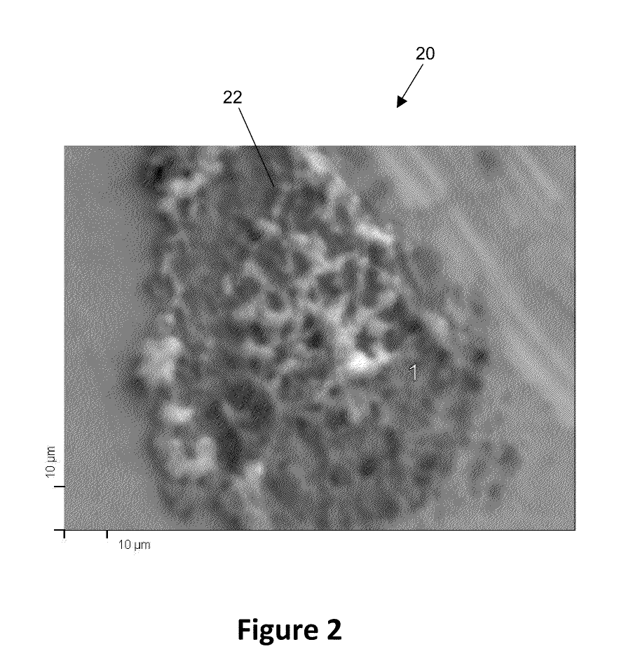

Referring now also to FIG. 2, there is shown a scanning electron microscope image of the FP smear 20 debris field after an FP layer is laser drilled 12 prior to cleaning. The debris is composed of dielectric layer fillers, FP segments and copper oxides 22 and forms a layer of FP smear 55 (FIG. 5) when plated after conventional wet cleaning prior to plating. The plasma etch 62a reacts with the copper layer 52a surface below the smear to create oxyfluorides in the surface of the copper layer 52a that can be removed with the addition of an acidic etchant such as HL-41 solution 61b following the plasma treatment. Introduction of the acidic etchant enhances removal of the oxide layer and the remaining FP segments from the bottom of the blind via 53b.

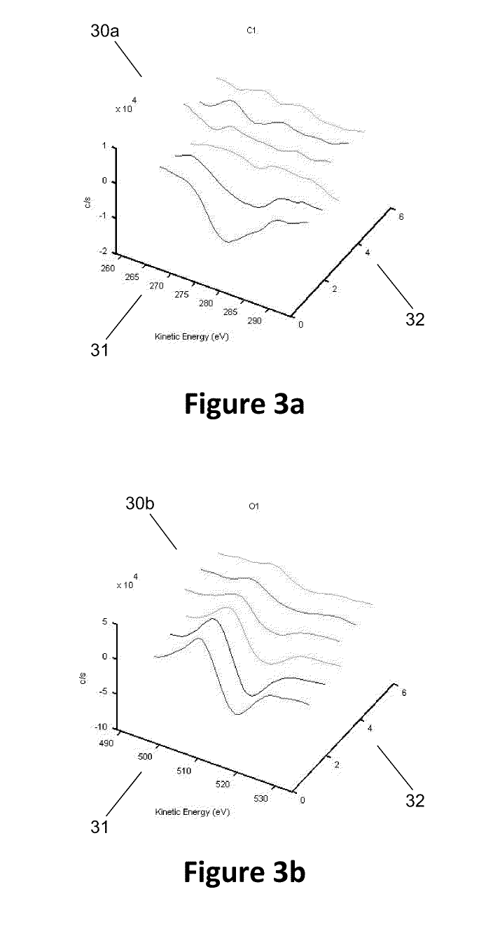

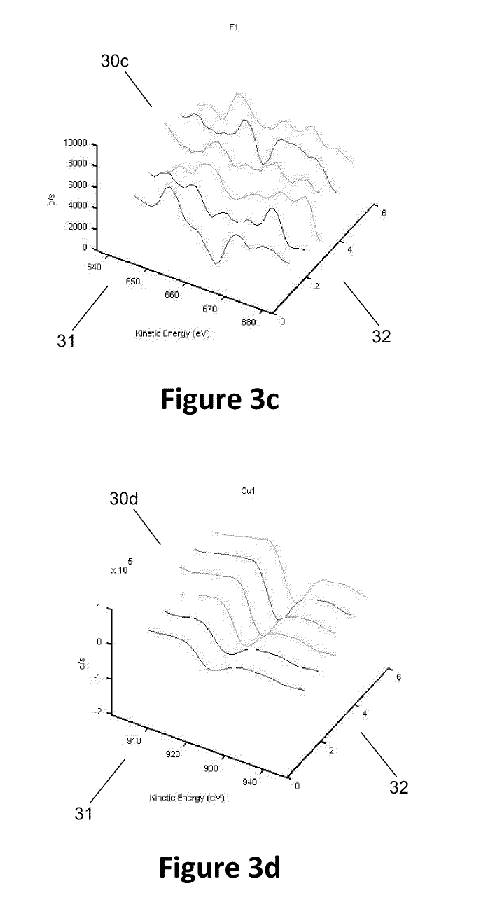

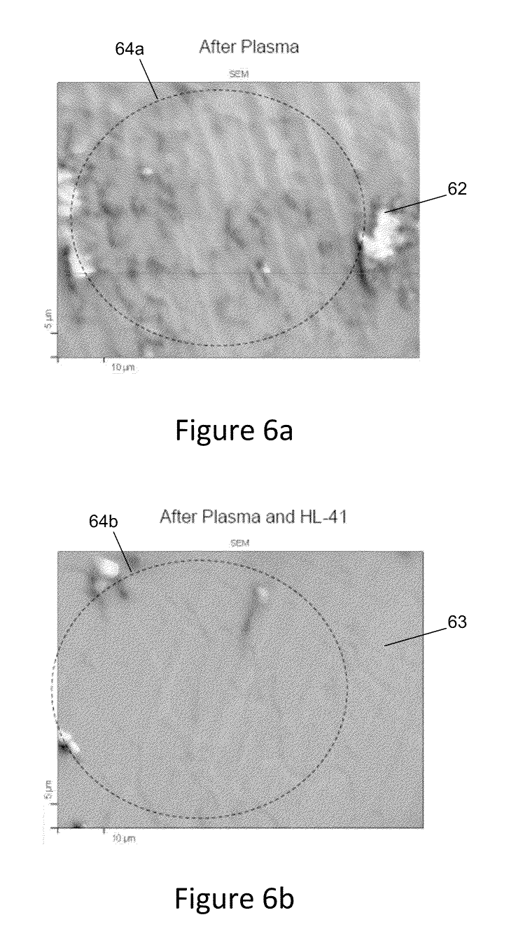

Referring now also to FIGS. 3a-d, Auger Electron Spectroscopy (AES) scans of the bottom of the blind via 64a (FIG. 6a) are shown after the RIE plasma step 61a has been performed as a first step in cleaning, prior to the HL-41 rinse 61b. The surface is partially oxidized to a depth of at least 200 angstroms and the RIE beam easily removes the fluorinated and carbonaceous layers. The Auger effect is an electronic process at the heart of AES resulting from the inter- and intrastate transitions of electrons in an excited atom. When an atom is probed by an external mechanism, such as a photon or a beam of electrons with energies in the range of 2 keV to 50 keV, a core state electron can be removed leaving behind a hole in an electron orbital shell. In this unstable state, the core hole is filled by an outer shell electron, whereby the electron moving to the lower energy level loses an amount of energy equal to the difference in orbital energies.

An emitted electron will have a specific kinetic energy 31 that is unique to an atom of a specific element. Analysis of the ejected electrons can yield information about the chemical composition of a surface. In addition, sputtering is used with Auger spectroscopy to perform depth-profiling experiments. Sputtering removes thin outer layers of a surface so that AES can be used to determine the underlying composition. Depth profiles 32 measure the intensity of the Auger peak above the target at precise depths. Precise depth milling through sputtering has made profiling a technique used for chemical analysis of nanostructure materials and thin films.

As can be seen, FIGS. 3a-d are carbon, oxygen, fluorine, and copper, respectively, and have randomness associated with the signal, mainly in the depth profile 32 is a result of the domains of copper oxyfluoride, FP residues, fillers, and metal oxyfluoride that remain, and a portion of the smear 22 that still exists due to insufficient cleaning. As such, this surface would not be ideal for plating.

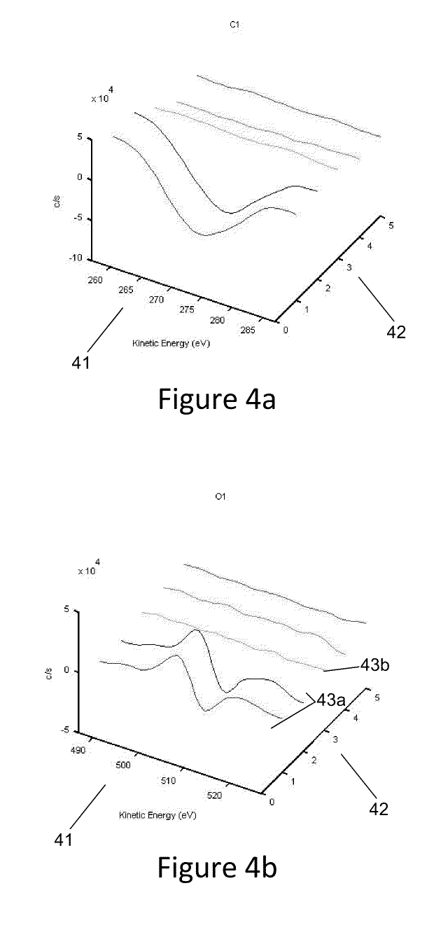

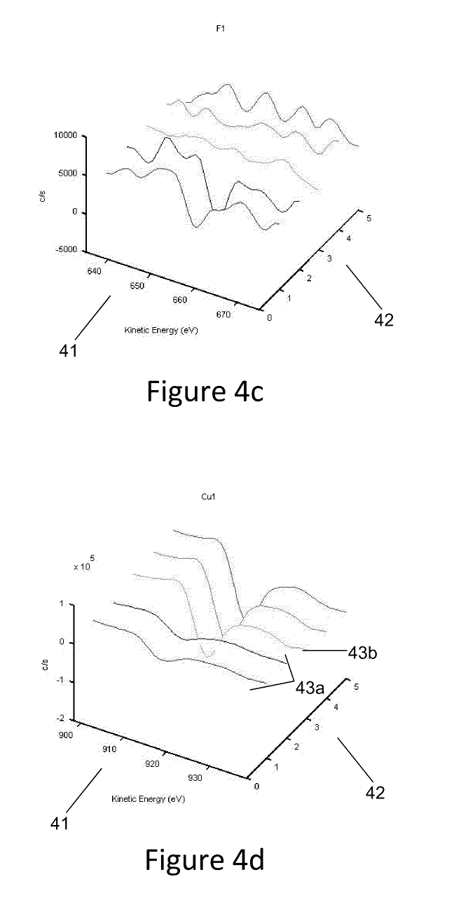

FIGS. 4a-d contain AES scans of the bottom of the blind via 64b (FIG. 6b) after the RIE plasma step 61a and the HL-41 rinse 61b has been performed. FIGS. 4a-d are carbon, oxygen, fluorine, and copper, respectively, and have specific kinetic energy 41 and depth profiles 42 created by sputtering. The process removes thin outer layers of a surface so that AES can be used to determine the underlying composition. The randomness associated with the signal apparent in FIGS. 3a-d, now compared with the post HL-41 rinse scans 61b of FIGS. 4a-d, show a marked decrease in randomness. FIGS. 3a-d illustrate that the newly exposed surface that contains a thin oxide layer of copper oxide on the order of <30 angstroms, as measured by AES depth profiling.

As seen in FIGS. 4b and 4d, a copper oxide layer spans the 0-1 tic marks 43a of depth profile 42. The next depth profile layer, corresponding to tic mark 2, 43b, has the copper oxide removed and has reached the base metallic copper. This depth profile describes a surface containing a thin oxide layer of copper oxide of the order of <30 angstroms that are easily removed by conventional pre-plating cleans to provide an ideal surface for the copper plating.

Referring now again to FIG. 5, a cross section of a composite structure 50 test coupon of Copper-Invar-Copper (CIC) 52 and FP layers 54a, 54b is shown. Also shown is a sectional view of two blind vias, 53a and 53b, on opposing sides of the CIC layer 52. The top blind via 53a has been plasma etch cleaned 61a only, the bottom blind via 53b has been cleaned with plasma etching 61a, and subsequently rinsed with HL-41 61b of acidic etchant. The CIC 52 core component has a layer structure with two exterior copper layers 52a containing 99.95% Cu. The core layer 52b contains a nickel/iron alloy (Invar) with a makeup of 36.5% Ni and 63.07% Fe, both core and copper layers having other trace elements, and a layer volume percentage ratio of 12.5%-75%-12.5% for exterior, core, and exterior, respectively.

After lamination of CIC layer 52 and FP layers 54a, 54b, the composite structure 50 was laser drilled 12 creating two blind vias, 53a, 53b, and the composite structure 50 was then subjected to the RIE plasma step 61a. Via 53b has also received the HL-41 rinse 61b. Then blind vias 53a, 53b were treated to conventional pre-plating cleans as known in the art to provide a surface that is favorable to applying a continuous conductive seed layer of copper, not shown, over the entire surface prior to full copper plating 57. The sectioned view shows the composite structure 50, copper layers 52a, core layer 52b, FP layers 54a, 54b, copper plating 57, and two blind vias, 53a, 53b. The layer of FP smear 55 has not been cleaned from the base of via 53a prior to the copper plating 57 being applied.

Referring now to FIGS. 6a-b there are shown two scanning electron microscope images, one of the bottom of a via 64a after the RIE plasma step 61a has been performed and via 64b after the RIE plasma step 61a and the HL-41 rinse 61b have been performed. Residues at bottom of via 64a after plasma etching 61a are random domains of organic and inorganic material. The surfaces become uniform after the use of HL-41 as by via 64b. The dotted line in the photo is an approximate diameter of a microvia, 75 μm.

Since other modifications and changes to the method provided for plating blind vias in microelectronic circuits containing fluoropolymer (FP) dielectric layers as such will be apparent to those skilled in the art, the invention is not considered limited to the description above for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. For use with a semiconductor printed circuit board assembly (PCBA) for use in electronic packages comprising a core layer of copper-invar-copper (CIC) having an upper surface and a lower surface; a first layer of dielectric substrate having a first side and a second side disposed on said upper surface of said core layer of CIC; a second layer of dielectric substrate having a third side and a fourth side disposed on said lower surface of said core layer of CIC, said layers being laminated together, forming a first subassembly; blind vias being laser drilled into said first side and said fourth side of said dielectric substrate layers, a method for plating blind vias, the steps comprising:
a) cleaning a blind via using reactive ion etch (RIE) plasma in said PCBA;
b) cleaning said blind via by using acidic etchant liquid solution;
c) pre-plating said blind via by a conventional cleaning process;
d) depositing a top and bottom seed copper layer on said first side and said fourth side of said dielectric substrate layer; and
e) depositing an upper and a lower layer of copper on said top and said bottom layer of said seed copper layer.

2. The method for plating blind vias as in claim 1, wherein said RIE cleaning step (a) comprises using a plasma of tetrafluoromethane (CF₄) and oxygen (O₂).

3. The method for plating blind vias as in claim 1, wherein said acidic etchant liquid solution comprises HL-41.

4. The method for plating blind vias as in claim 1, wherein said first and said layer of dielectric substrate comprise at least one material taken from the group: polyimide (Kapton), polyester (Mylar), FEP (Teflon), and fluoropolymer (FP).

5. A method of forming a printed circuit board assembly (PCBA) for use in electronic packages, comprising:
a) providing a core layer of copper-invar-copper (CIC) having an upper surface and a lower surface;
b) providing a first layer of dielectric substrate having a first side and a second side disposed on said upper surface of said core layer of CIC;
c) providing a second layer of dielectric substrate having a third side and a fourth side disposed on said lower surface of said core layer of CIC;
d) laminating said CIC and dielectric layers together, forming a first subassembly;
e) laser drilling blind vias into said first side and said fourth side of said dielectric substrate layers;
f) cleaning a blind via using reactive ion etch (RIE) plasma in said PCBA;
g) cleaning said blind via by using acidic etchant liquid solution;
h) pre-plating said blind via by a conventional cleaning process;
i) depositing a top and bottom seed copper layer on said first side and said fourth side of said dielectric substrate layer; and
j) depositing an upper and a lower layer of copper on said top and said bottom layer of said seed copper layer.

6. The method of forming a printed circuit board assembly for use in electronic packages as in claim 5, wherein said RIE cleaning step (f) comprises using a plasma of tetrafluoromethane (CF₄) and oxygen (O₂).

7. The method of forming a printed circuit board assembly for use in electronic packages as in claim 5, wherein said acidic etchant liquid solution comprises HL-41.

8. The method of forming a printed circuit board assembly for use in electronic packages as in claim 5, wherein said first and said layer of dielectric substrate comprise at least one material taken from the group: polyimide (Kapton), polyester (Mylar), FEP (Teflon), and fluoropolymer (FP).

9. A printed circuit board assembly (PCBA) for use in electronic packages, comprising:
a) a core layer of copper-invar-copper (CIC) having an upper surface and a lower surface;
b) a first layer of dielectric substrate having a first side and a second side disposed on said upper surface of said core layer of CIC;
c) a second layer of dielectric substrate having a third side and a fourth side disposed on said lower surface of said core layer of CIC, said CIC and dielectric layers being laminated together, forming a first subassembly;
d) blind vias laser drilled into said first side and said fourth side of said dielectric substrate layers, said vias being cleaned using reactive ion etch (RIE) plasma in said PCBA, then by acidic etchant liquid solution, and then being pre-plated by a conventional cleaning process;
e) a top and bottom seed copper layer disposed on said first side and said fourth side of said dielectric substrate layer; and
f) an upper and a lower layer of copper on said top and said bottom layer of said seed copper layer.

10. The printed circuit board assembly for use in electronic packages as in claim 9, wherein said RIE cleaning step (d) comprises using a plasma of tetrafluoromethane (CF₄) and oxygen (O₂).

11. The printed circuit board assembly for use in electronic packages as in claim 9, wherein said acidic etchant liquid solution comprises HL-41.

12. The printed circuit board assembly for use in electronic packages as in claim 9, wherein said first and said layer of dielectric substrate comprise at least one material taken from the group: polyimide (Kapton), polyester (Mylar), FEP (Teflon), and fluoropolymer (FP).
